(19) United States
(12) Patent Application Publication
(10) Pub. No.: US 2023/0402822 A1
(43) Pub. Date: Dec. 14, 2023

(54) MANUFACTURING METHOD OF SEMICONDUCTOR DEVICE

(71) Applicants: National Tsing Hua University, Hsinchu City (TW); Turning Point Lasers Corporation, Hsinchu City (TW)

(72) Inventors: Ci-Ling Pan, Hsinchu City (TW); Chi-Luen Wang, Hsinchu City (TW); Hung-Sheng Lee, Taipei City (TW); Li-Chang Tsou, Hsinchu City (TW); Tzu-Neng Lin, Hsinchu County (TW)

(73) Assignees: National Tsing Hua University, Hsinchu City (TW); Turning Point Lasers Corporation, Hsinchu City (TW)

(21) Appl. No.: 17/983,400

(22) Filed: Nov. 9, 2022

(30) Foreign Application Priority Data
Jun. 9, 2022 (TW) 111121484

(51) Int. Cl. H01S 5/343; H01S 5/028; H01S 5/20; H01S 5/042

(52) U.S. Cl. CPC H01S 5/343; H01S 5/028; H01S 5/2027; H01S 5/2031; H01S 5/04256

(57) ABSTRACT

A manufacturing method of a semiconductor device includes: providing a semiconductor stack layer, wherein the semiconductor stack layer includes a first type semiconductor layer, a quantum well layer, and a second type semiconductor layer stacked in sequence; growing an aluminum nitride layer on the second type semiconductor layer; and annealing the aluminum nitride layer to achieve quantum well intermixing.

### CROSS-REFERENCE TO RELATED APPLICATION

This application claims the priority benefit of Taiwan application serial no. 111121484, filed on Jun. 9, 2022. The entirety of each of the above-mentioned patent applications is hereby incorporated by reference herein and made a part of this specification.

### BACKGROUND

### Technical Field

The disclosure relates to a manufacturing method of semiconductor device.

### Description of Related Art

Different semiconductor materials may be fabricated into a variety of optoelectronic devices, including light-emitting devices, light receivers, light guides, or modulators. In the field of light-emitting devices, high-power semiconductor lasers are widely used in advanced manufacturing and other fields, and are key modules. However, a laser device requires a resonant cavity, and the two ends of the resonant cavity require mirror surfaces. The output power of such a laser is limited by the deterioration of the device characteristics caused by the catastrophic optical damage (COD) of the mirror surface. Therefore, the non-absorbing mirror (NAM) structure is a key technology for the fabrication of high-power semiconductor lasers. In short, NAMs are designed to increase the energy gap at the mirror end (relative to the energy gap of the active layer in the region far from the mirror end), lower the absorption coefficient, reduce the photoexcited carrier density, and reduce the generation of heat from nonradiative recombination to improve the COD threshold at the mirror end and the reliability of a laser diode device. This is based on the principle of quantum well intermixing in the structure of laser diode devices.

Therefore, how to elevate the degree of elevation of the energy gap of the mirror surface and increase the reliability of the device during a quantum well intermixing is in urgent need to be developed by the industry and various research units.

### SUMMARY

The disclosure provides a manufacturing method of a semiconductor device, which may effectively elevate the degree of elevation of the energy gap of the mirror surface, and may effectively increase the reliability of the device during a quantum well intermixing.

An embodiment of the disclosure provides a method for manufacturing a semiconductor device, including the following process. A semiconductor stack layer is provided, in which the semiconductor stack layer includes a first type semiconductor layer, a quantum well layer, and a second type semiconductor layer stacked in sequence. An aluminum nitride layer is grown on the second type semiconductor layer. The aluminum nitride layer is annealed to achieve quantum well intermixing.

In the manufacturing method of the semiconductor device according to the embodiment of the disclosure, the growing method of the aluminum nitride layer and the annealing method of the aluminum nitride layer is adopted to achieve the quantum well intermixing. Experiments have shown that adopting the annealing of the aluminum nitride layer may effectively elevate the degree of elevation of energy gap of the mirror end during the quantum well intermixing, and the aluminum nitride layer has excellent mechanical and thermal properties, which may effectively improve the reliability of devices.

### BRIEF DESCRIPTION OF THE DRAWING

FIG. 1A and FIG. 1B are cross-sectional schematic diagrams illustrating the flow of a manufacturing method of a semiconductor device according to an embodiment of the disclosure.

FIG. 2A illustrates the photoluminescence spectrum of the semiconductor stack layer of FIG. 1A without annealing the aluminum nitride layer and after annealing the aluminum nitride layer at 800° C., 850° C., 900° C., and 950° C.

FIG. 2B is a blue shift degree distribution diagram of the photoluminescence spectrum of the semiconductor stack layer after covering the second type semiconductor layer of FIG. 1A with an aluminum nitride layer, a silicon nitride layer, or a silicon dioxide layer and annealing at various different temperatures.

FIG. 3A is a curve diagram of the operating power versus the operating current of the semiconductor device of FIG. 1B.

FIG. 3B is a curve diagram showing the ratio of the output power to the initial output power of the semiconductor device of FIG. 1B after a period of use relative to the use time.

### DETAILED DESCRIPTION OF DISCLOSED EMBODIMENTS

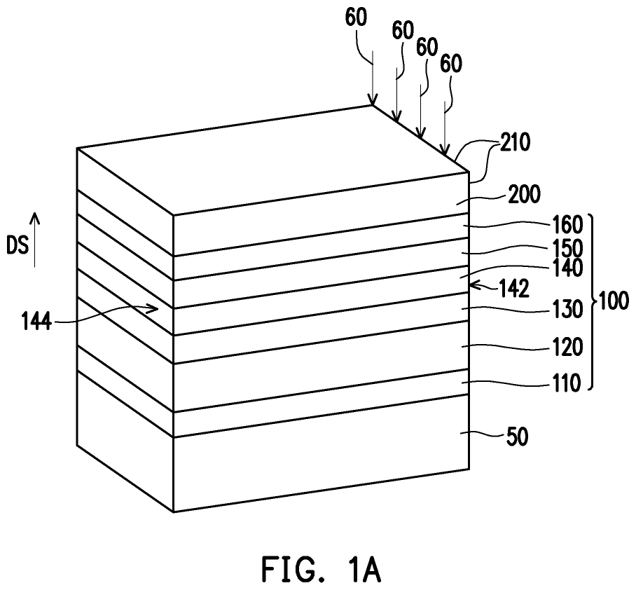

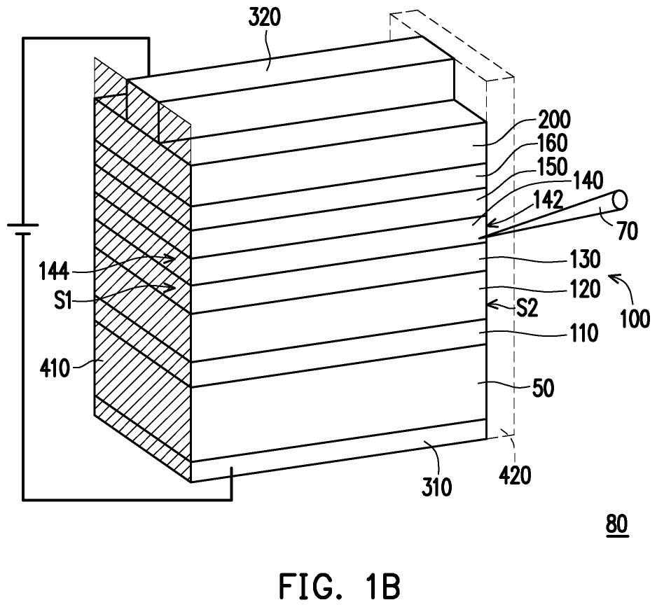

FIG. 1A and FIG. 1B are cross-sectional schematic diagrams illustrating the flow of a manufacturing method of a semiconductor device according to an embodiment of the disclosure. Referring to FIG. 1A and FIG. 1B, the manufacturing method of the semiconductor device of this embodiment includes the following steps. First, referring to FIG. 1A, a semiconductor stack layer 100 is provided, in which the semiconductor stack layer 100 includes a first type semiconductor layer 120, a quantum well layer 140 and a second type semiconductor layer 160 stacked in sequence. The first type is, for example, n type, and the second type is, for example, p type. However, in other embodiments, the first type may be p type and the second type may be n type. In this embodiment, the semiconductor stack layer 100 further includes a first type waveguide layer 130 and a second type waveguide layer 150, the first type waveguide layer 130 is disposed between the quantum well layer 140 and the first type semiconductor layer 120, the second type waveguide layer 150 is disposed between the quantum well layer 140 and the second type semiconductor layer 160, in which the semiconductor stack layer 100 forms a semiconductor laser structure, the first type semiconductor layer 120 is a first type cladding layer, and the second type semiconductor layer 160 is a second type cladding layer.

In this embodiment, a substrate 50 is disposed under the first type semiconductor layer 120. Specifically, the substrate 50 is, for example, a growth substrate, and the semiconductor stack layer 100 may be formed by sequentially growing a first type buffer layer 110, a first type semiconductor layer 120, a first type waveguide layer 130, the quantum well layer 140, the second type waveguide layer 150, and the second type semiconductor layer 160. In addition, the quantum well layer 140 may be a multiple quantum well layer or a single quantum well layer.

In this embodiment, the materials of the substrate 50, the first type buffer layer 110, the first type semiconductor layer 120, the first type waveguide layer 130, the quantum well layer 140, the second type waveguide layer 150, and the second type semiconductor layer 160 is, for example, a group III-V semiconductor. However, in other embodiments, it may also be a group II-VI semiconductor or other semiconductors. In addition, the substrate 50 may be a sapphire substrate. In one embodiment, the substrate 50 is, for example, an n type gallium arsenide substrate, the material of the first type buffer layer 110 is, for example, n type gallium arsenide, and the material of the first type semiconductor layer 120 is, for example, n type indium aluminum phosphide, the material of the first type waveguide layer 130 is, for example, n type indium aluminum gallium phosphide, the material of the quantum well layer 140 is, for example, indium gallium phosphide, the material of the second type waveguide layer 150 is, for example, p type indium aluminum gallium phosphide, and the material of the second type semiconductor layer 160 is, for example, p type indium aluminum phosphide, but the disclosure is not limited thereto.

Next, an aluminum nitride layer 200 is grown on the second type semiconductor layer 160. Then, the aluminum nitride layer 200 is annealed to achieve quantum well intermixing. In this embodiment, the quantum well layer 140 includes a light-exiting side 142 and a reflecting side 144 opposite to each other, and the arrangement direction of the light-exiting side 142 and the reflecting side 144 is perpendicular to a stacking direction DS of the semiconductor stack layer 100. A laser resonant cavity may be formed between the light-exiting side 142 and the reflecting side 144. In this embodiment, the annealing method of the aluminum nitride layer 200 may be to heat a portion 210 of the aluminum nitride layer 200 located above the light-exiting side 142 with a laser beam 60. When the portion 210 of the aluminum nitride layer 200 located above the light-exiting side 142 is heated by the laser beam 60, the elements of the quantum well layer 140 located on the light-exiting side 142 (e.g., group III elements) produces a diffusion effect. Elements (e.g., group III elements) of the film adjacent to the quantum well layer 140 on the side near the light-exiting side 142 also produce a diffusion effect, such that the quantum well layer 140 and elements (e.g., group III elements) of the film adjacent to the quantum well layer 140 near the light-exiting side 142 are intermixed (e.g., group III elements in the energy well layer and the energy barrier layer are intermixed), so that the energy gap of the quantum well layer 140 on the light-exiting side 142 is increased to form a non-absorbing mirror structure. The fabricating method of using the heating of the aluminum nitride layer 200 to achieve quantum well intermixing to form a non-absorbing mirror structure is impurity free vacancy disordering (IFVD), which minimally degrades the optical and electrical properties of the device. In addition, in the present embodiment, heating the portion 210 of the aluminum nitride layer 200 located above the light-exiting side 142 with the laser beam 60 is adopting laser annealing to perform local treatment in the selected region, which may effectively reduce the thermal budget and shorten the process time. In one embodiment, the edge portion (i.e., the portion 210) of the aluminum nitride layer 200 located above the light-exiting side 142 may be scanned by the laser beam 60, but the disclosure is not limited thereto. In other embodiments, the aluminum nitride layer 200 may also be annealed by other annealing methods, such as annealing by adopting a high temperature furnace.

After that, referring to FIG. 1B, a first electrode 310 is formed, which is electrically connected to the first type semiconductor layer 120. In this embodiment, the first electrode 310 is formed on the side of the substrate 50 opposite to the first type semiconductor layer 120, and the first electrode 310 is electrically connected to the first type semiconductor layer 120 through the substrate 50. In addition, a second electrode 320 is formed on the aluminum nitride layer 200, and the second electrode 320 is electrically connected to the second type semiconductor layer 160. Specifically, the aluminum nitride layer 200 may be selectively etched, that is, a portion of the aluminum nitride layer 200 may be etched to expose a portion of the second type semiconductor layer 160. Then, the second electrode 320 is formed on the exposed portion of the second type semiconductor layer 160 and the aluminum nitride layer 200.

In addition, a reflective coating 410 may be formed on a first side S1 of the semiconductor stack layer 100, in which the reflecting side 144 is located on the first side S1. Furthermore, an anti-reflection coating 420 may be formed on a second side S2 of the semiconductor stack layer 100, in which the light-exiting side 142 is located on the second side S2. In this embodiment, the reflective coating 410 is, for example, a highly reflective coating, which may have a reflectivity of greater than 90% for the light emitted by the quantum well layer 140. The anti-reflection coating 420 and the non-absorbing mirror structure on the light-exiting side 142 may have a reflectivity of less than 10% for the light emitted by the quantum well layer 140. In this way, when a forward voltage is applied to the second electrode 320 and the first electrode 310, the light emitted by the quantum well layer 140 will resonate in the resonant cavity formed between the reflecting side 144 and the light-exiting side 142, and a laser beam 70 is emitted from the light-exiting side 142. In this way, the formed overall structure is a semiconductor device 80, and in this embodiment, the semiconductor device 80 is, for example, a semiconductor laser device. However, in other embodiments, the semiconductor device 80 may also be changed to other semiconductor devices, such as other light-emitting devices (e.g., light-emitting diodes), light receivers, light guides, or modulators, as long as the manufacturing method of the semiconductor device adopts an aluminum nitride layer that is disposed on the semiconductor stack layer and is annealed, then they all belong to the protection scope of the disclosure.

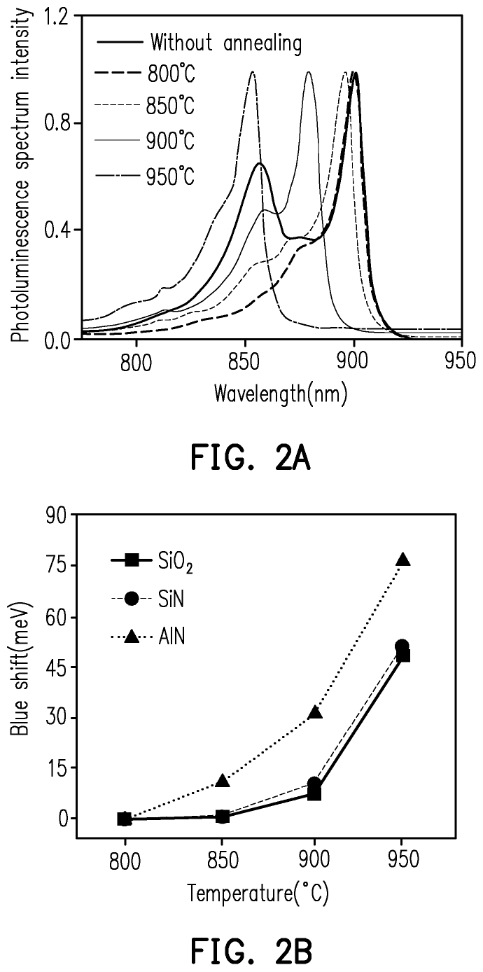

FIG. 2A illustrates the photoluminescence spectrum of the semiconductor stack layer of FIG. 1A without annealing the aluminum nitride layer and after annealing the aluminum nitride layer at 800° C., 850° C., 900° C., and 950° C., and FIG. 2B is a blue shift degree distribution diagram of the photoluminescence spectrum of the semiconductor stack layer after covering the second type semiconductor layer of FIG. 1A with an aluminum nitride layer, a silicon nitride layer, or a silicon dioxide layer and annealing at various different temperatures. Referring to FIG. 1A and FIG. 2A, after the aluminum nitride layer is adopted and annealed at 950° C., the blue shift of the peak of the photoluminescence spectrum of the semiconductor stack layer 100 relative to the peak of the photoluminescence spectrum of the semiconductor stack layer 100 when the aluminum nitride layer is not annealed is as high as 47.9 nanometers (nm), and it may be seen from FIG. 2B that adopting an aluminum nitride (AlN) layer 200 for annealing may achieve a higher degree of blue shift when compared with adopting a silicon nitride (SiN) layer for annealing or a silicon dioxide (SiO2) layer for annealing. It may be seen from the experimental data in FIG. 2A and FIG. 2B that adopting the aluminum nitride layer 200 for annealing may effectively elevate the degree of elevation of the energy gap of the mirror surface during the quantum well intermixing, so that the energy gap of the non-absorbing mirror structure on the light-exiting side 142 is greater and less likely to absorb the light emitted by the quantum well layer 140, thereby achieving a higher COD threshold and a more reliable semiconductor device 80. On the other hand, compared with the silicon dioxide layer, the aluminum nitride layer 200 has superior mechanical and thermal properties, that is, compared with the silicon dioxide layer, the aluminum nitride layer 200 needs to be subjected to heat of a higher temperature to generate the same stress. Therefore, the properties of the aluminum nitride layer 200 are relatively stable, which may effectively improve the reliability of the semiconductor device 80.

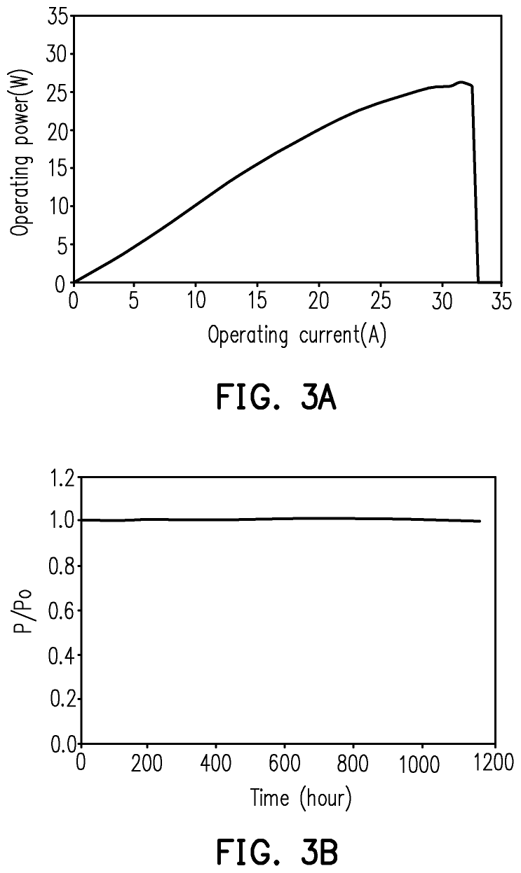

FIG. 3A is a curve diagram of the operating power versus the operating current of the semiconductor device of FIG. 1B, and FIG. 3B is a curve diagram showing the ratio of the output power to the initial output power of the semiconductor device of FIG. 1B after a period of use relative to the use time. Referring to FIG. 3A and FIG. 1B, it may be seen from FIG. 3A that the COD threshold of the semiconductor device 80 is about 26.5 watts (W), thus it may be verified that the semiconductor device 80 of the embodiment of the disclosure has a high COD threshold. In addition, referring to FIG. 3B and FIG. 1B, it may be seen from FIG. 3B that the ratio of an initial output power P of the semiconductor device 80 to an output power Po of the semiconductor device 80 after a period of use is quite stable, and it is unlikely that the ratio rises as the use time increases. It may be seen from FIG. 3B that the ratio of the initial output power P of the semiconductor device 80 to the output power Po of the semiconductor device 80 after 1150 hours of use is about 1.007. It may be seen that the semiconductor device 80 is less likely to cause a drop in the output power Po due to a prolonged use time.

To sum up, in the manufacturing method of the semiconductor device according to the embodiment of the disclosure, the growing method of the aluminum nitride layer and the annealing method of the aluminum nitride layer is adopted to achieve the quantum well intermixing. Experiments have shown that adopting the annealing of the aluminum nitride layer may effectively elevate the degree of elevation of energy gap of the mirror end during the quantum well intermixing, and the aluminum nitride layer has excellent mechanical and thermal properties, which may effectively improve the reliability of devices.

What is claimed is:

1. A manufacturing method of a semiconductor device, comprising:
providing a semiconductor stack layer, wherein the semiconductor stack layer comprises a first type semiconductor layer, a quantum well layer, and a second type semiconductor layer stacked in sequence;
growing an aluminum nitride layer on the second type semiconductor layer; and
annealing the aluminum nitride layer to achieve quantum well intermixing.

2. The manufacturing method according to claim 1, wherein the semiconductor stack layer further comprises:
a first waveguide layer, disposed between the quantum well layer and the first type semiconductor layer; and
a second waveguide layer, disposed between the quantum well layer and the second type semiconductor layer, wherein the semiconductor stack layer forms a semiconductor laser structure.

3. The manufacturing method according to claim 2, wherein the quantum well layer comprises a light-exiting side and a reflecting side opposite to each other, and an arrangement direction of the light-exiting side and the reflecting side is perpendicular to a stacking direction of the semiconductor stack layer.

4. The manufacturing method according to claim 3, wherein the annealing the aluminum nitride layer comprises:
heating a portion of the aluminum nitride layer located above the light-exiting side with a laser beam.

5. The manufacturing method according to claim 4, wherein when a portion of the aluminum nitride layer located above the light-exiting side is heated by the laser beam, a band gap of the portion of the quantum well layer at the light-exiting side increases, to form a non-absorbing mirror structure.

6. The manufacturing method according to claim 3, further comprising:
forming a reflective coating on a first side of the semiconductor stack layer, wherein the reflecting side is located on the first side; and
forming an anti-reflection coating on a second side of the semiconductor stack layer, wherein the light-exiting side is located on the second side.

7. The manufacturing method according to claim 1, wherein the quantum well layer is a multiple quantum well layer.

8. The manufacturing method according to claim 1, wherein the quantum well layer is a single quantum well layer.

9. The manufacturing method according to claim 1, wherein a substrate is disposed under the first type semiconductor layer.

10. The manufacturing method according to claim 1, further comprising:
forming a first electrode, wherein the first electrode is electrically connected to the first type buffer layer; and
forming a second electrode on the aluminum nitride layer, and electrically connecting the second electrode to the second type semiconductor layer.
